(19) United States
(12) Patent Application Publication
(10) Pub. No.: US 2025/0364192 A1
(43) Pub. Date: Nov. 27, 2025

(54) SWITCH DEVICE AND VEHICULAR SWITCH DEVICE

(71) Applicant: KABUSHIKI KAISHA TOKAI RIKA DENKI SEISAKUSHO, Aichi (JP)

(72) Inventor: Seiji HAYASHI, Aichi (JP)

(73) Assignee: KABUSHIKI KAISHA TOKAI RIKA DENKI SEISAKUSHO, Aichi (JP)

(21) Appl. No.: 18/993,844

(22) PCT Filed: May 12, 2023
(86) PCT No.: PCT/JP2023/017916

§ 371 Date: Jan. 13, 2025

(30) Foreign Application Priority Data
Aug. 5, 2022 (JP) 2022-125833

(51) Int. Cl. H01H 13/14; B60K 35/10; G06F 3/041; G06F 3/044; H03K 17/96

(52) U.S. Cl. CPC H01H 13/14; B60K 35/10; G06F 3/04186; G06F 3/044; H03K 17/9622; B60K 2360/1446; B60K 2360/782; G06F 2203/04108

(57) ABSTRACT

A switch device includes an operation knob including plural operation surfaces, and an operation detection unit that detects an operation performed by operating one, or not less than two, of the plural operation surfaces. Adjacent operation surfaces of the plural operation surfaces have different angles with a boundary region therebetween.

### CROSS-REFERENCE TO RELATED APPLICATIONS

The present patent application claims the priority of Japanese patent application No. 2022/125833 filed on Aug. 5, 2022, and the entire contents of Japanese patent application No. 2022/125833 are hereby incorporated by reference.

### TECHNICAL FIELD

The present invention relates to a switch device and a vehicular switch device.

### BACKGROUND ART

An in-vehicle switch device is known which has improved operability of a display unit used to display settings or instructions, etc., for in-vehicle functions and to perform operations (see, e.g., PTL 1).

The switch device disclosed in PTL 1 includes the display unit provided with a touch-panel-type display screen to display images of in-vehicle functions, an operation unit to change the vehicle state based on the images of the in-vehicle functions displayed on the display screen, and a control circuit that controls display of the images of the in-vehicle functions and also controls the in-vehicle functions according to operations performed on the operation unit. The operation unit of this switch device includes an operating-plate portion that can be moved along the display screen of the display unit, a protruding switch portion provided on the operating-plate portion, and a touch sensor.

### CITATION LIST

### Patent Literatures

PTL 1: JP 2013/220736 A

### SUMMARY OF INVENTION

The switch device disclosed in PTL 1 is configured to include the protruding switch portion provided on the operating-plate portion and to display settings and instructions, etc., for the in-vehicle functions according to operations performed on the protruding switch portion and the touch sensor, thereby improving the operability of the display unit. However, the problem is that since the operating-plate portion is present, e.g., it is not easy to perform an operation on the touch-panel-type display screen when performing an operation while distinguishing between touch operation and tracing operation.

It is an object of the invention to provide a switch device and a vehicular switch device that are excellent in operability.
(1) According to an embodiment of the invention, a switch device comprises:
an operation knob comprising a plurality of operation surfaces; and
an operation detection unit that detects an operation performed by operating one, or not less than two, of the plurality of operation surfaces,
wherein adjacent operation surfaces of the plurality of operation surfaces have different angles with a boundary region therebetween.
(2) The switch device defined in (1) may be configured such that the operation detection unit detects a tracing operation or a pressing operation as the operation on one, or not less than two, of the plurality of operation surfaces.
(3) The switch device defined in (2) may further comprise a control unit that determines a direction of a tracing operation performed on not less than two of the plurality of operation surfaces and/or determines one of the plurality of operation surfaces that has been pressed, based on a detection result of the operation detection unit.
(4) The switch device defined in (1) may be configured such that the operation detection unit comprises an electrostatic capacitance sensor that is provided in at least a region corresponding to one of the operation surfaces and detects touch or proximity to the operation surface.
(5) The switch device defined in (4) may be configured such that the adjacent operation surfaces meet at the boundary region in a continuous manner, and the electrostatic capacitance sensors are provided in regions respectively corresponding to the adjacent operation surfaces.
(6) The switch device defined in (1) may be configured such that the operation detection unit comprises a tactile switch that is provided under at least one of the plurality of operation surfaces and is turned on and off by a pressing operation.
(7) The switch device defined in (1) may be configured such that the boundary region is a boundary at which the adjacent operation surfaces meet, and comprises a boundary line, or a step portion with a level difference sandwiched between edges of two of the operation surfaces.
(8) The switch device defined in (1) may be configured such that the plurality of operation surfaces comprise the adjacent operation surfaces meeting in a mountain fold or a valley fold at the boundary region, or the adjacent operation surfaces meeting with the step portion therebetween, or a combination thereof.
(9) The switch device defined in (1) may be configured such that each of the plurality of operation surfaces comprises a flat surface or a curved surface.
(10) The switch device defined in any one of (1) to (9) may be a vehicular switch device that is mounted on a steering wheel of a vehicle.

### Advantageous Effects of Invention

According to an embodiment the invention, it is possible to provide a switch device and a vehicular switch device that are excellent in operability.

### BRIEF DESCRIPTION OF DRAWINGS

FIG. 1A is a plan view showing a switch device in an embodiment.

FIG. 1B is a cross-sectional view showing a cross section taken along line A-A of FIG. 1A.

FIG. 1C is a cross-sectional view showing a cross section taken along line B-B of FIG. 1A.

FIG. 2A is a front view showing the switch devices in the embodiment mounted on a steering wheel of a vehicle when viewed from the driver's seat side.

FIG. 2B is an enlarged front view showing an operation knob of the switch device in the embodiment.

FIG. 3 is a block diagram including a control unit of the switch device in the embodiment.

FIG. 4 is a flowchart showing the overall operation of the switch device in the embodiment.

FIG. 5 is a flowchart showing an operation of a tracing determination part in the flowchart shown in FIG. 4.

FIG. 6 is a flowchart showing an operation of a press determination part in the flowchart shown in FIG. 4.

FIG. 7 is a front view showing another embodiment to show another division pattern of the operation knob of the switch device.

### DESCRIPTION OF EMBODIMENTS

### Embodiment of the Invention

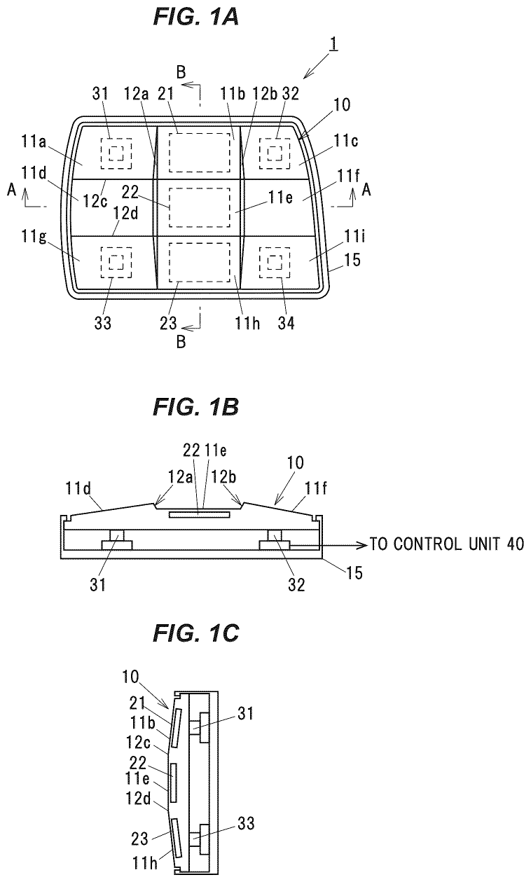

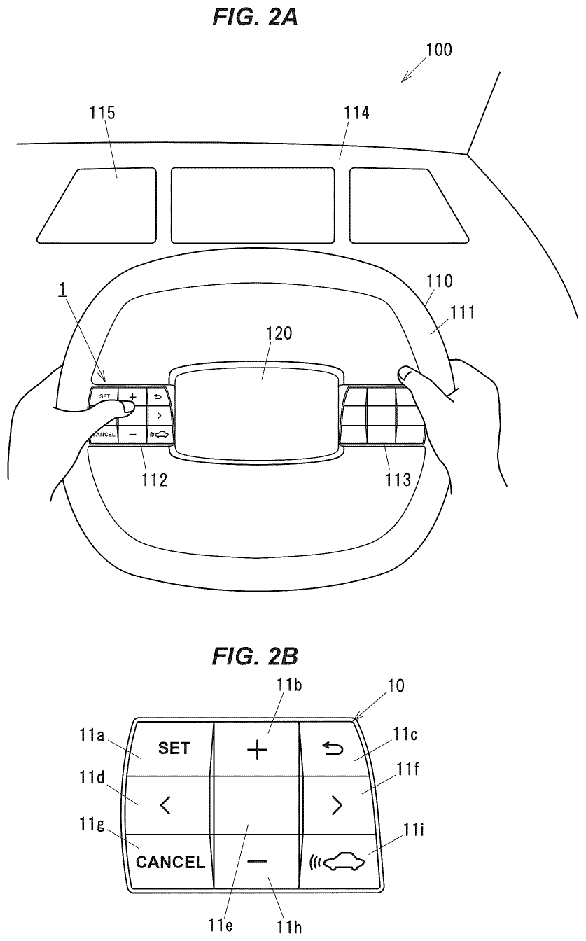

As shown in FIGS. 1A, 1B, 1C, and 2B, a switch device 1 in an embodiment of the invention is a switch device that has an operation knob 10 with plural operation surfaces (11a, 11b, 11c, 11d, 11e, 11f, 11g, 11h, and 11i) and detects operation performed by operating one, or not less than two, of the operation surfaces. In the present embodiment, the case of having nine operating positions, which is defined by boundary regions (12a, 12b, 12c, 12d), as the plural operation surfaces will be described. The switch device 1 has the operation knob 10 with the plural operation surfaces (11a to 11i), and a main body 15 that supports the operation knob 10.

Adjacent operation surfaces have different angles with the boundary regions therebetween, and the operation knob includes an electrostatic capacitance sensor provided in at least a region corresponding to one operation surface to detect touch or proximity to the operation surface. The regions corresponding to the operation surfaces are regions respectively including the operation surfaces (11a to 11i) and the interior portion of the operation knob 10 from the operation surfaces (11a-11i), and in the present embodiment, touch detection electrodes 21, 22, and 23 are embedded at a predetermined depth from the operation surfaces (11b, 11e, and 11h) constituting the front surface of the operation knob 10, as shown in FIGS. 1B and 1C.

As shown in FIG. 1C, the adjacent operation surfaces (11b, 11e, 11h) meet at the boundary regions in a continuous manner, and the touch detection electrodes 21, 22, and 23 are provided as electrostatic capacitance sensors 20 in the regions respectively corresponding to the adjacent operation surfaces, which makes it possible to detect tracing operation.

The operation surfaces are surfaces defined by being sandwiched between the boundary regions and constitute a front surface of a knob to be operated by an operator. Tracing operation and pressing (depressing) operation are performed on the operation surfaces (11a to 11i). The tracing operation is a continuous touch operation or slide operation on not less than two operation surfaces, and the touch operation is detected based on contact or proximity of an operator's finger, etc. to the electrostatic capacitance sensor. The pressing (depressing) operation is performed by pressing or depressing each operation surface. In the following description, the case where a pressing operation is performed will be described.

As shown in FIGS. 1A, 1B, and 1C, the operation knob 10 has nine operation surfaces (11a to 11i) defined by the boundary regions (12a, 12b, 12c, 12d), and the touch detection electrodes 21, 22, and 23 are provided as the electrostatic capacitance sensors 20 in the regions corresponding to the operation surfaces (11b, 11e, 11h) to detect tracing operation. When an operator's finger comes into contact with or proximity to the touch detection electrodes 21, 22, and 23, a capacitor is formed between the finger and the touch detection electrodes 21, 22, and 23, hence, touch or proximity to the touch detection electrodes 21, 22, and 23 can be detected by a control unit 40 (described later) by detecting a change in capacitance.

The boundary region (12a, 12b, 12c, 12d) is a boundary at which adjacent operation surfaces (11a to 11i) meet, and is a boundary line, or a step portion (inclined surface) with a level difference sandwiched between edges of two operation surfaces. In the present embodiment, a vertical three-tiered and mountain-fold (outward-fold) type is adopted, and as shown in FIG. 1A, the boundary regions 12a, 12b respectively separating the operation surfaces (11a, 11d, 11g) from the operation surfaces (11b, 11e, 11h) and the operation surfaces (11b, 11e, 11h) from the operation surfaces (11c, 11f, 11i) are step portions (inclined surfaces) each with a level difference sandwiched between edges of two adjacent operation surfaces.

As shown in FIG. 1B, the adjacent operation surfaces 11d and 11e meet with the boundary region 12a therebetween. The boundary region 12a is a step portion (inclined surface) with a level difference, and the operation surface 11e, which is a horizontal surface, and the operation surface 11d, which is a surface inclined to the left, are formed at different angles. Likewise, the adjacent operation surfaces 11e and 11f meet with the boundary region 12b therebetween. The boundary region 12b is a step portion (inclined surface) with a level difference, and the operation surface 11e, which is a horizontal surface, and the operation surface 11f, which is a surface inclined to the right, are formed at different angles.

On the other hand, as shown in FIG. 1A, the boundary regions 12c and 12d respectively separating the operation surfaces (11a, 11b, 11c) from the operation surfaces (11d, 11e, 11f) and the operation surfaces (11d, 11e, 11f) from the operation surfaces (11g, 11h, 11i) are boundary lines each between two adjacent operation surfaces.

As shown in FIG. 1C, the adjacent operation surfaces 11b and 11e meet at the boundary region 12c in a continuous manner. The boundary region 12c is a boundary line at which the respective edges of the adjacent operation surfaces 11b and 11e meet. When the switch device is placed flat, the operation surface 11e, which is a horizontal surface, and the operation surface 11b, which is a surface inclined to the right, are formed at different angles, in a similar manner to FIG. 1B. Similarly, the adjacent operation surfaces 11e and 11h meet at the boundary region 12d in a continuous manner. The boundary region 12d is a boundary line at which the respective edges of the adjacent operation surfaces 11e and 11h meet. The operation surface 11e, which is a horizontal surface, and the operation surface 11h, which is a surface inclined to the left, are formed at different angles.

The plural operation surfaces are adjacent operation surfaces meeting in a mountain fold or a valley fold at the boundary region, or adjacent operation surfaces meeting with the step portion therebetween, or a combination thereof. As shown in FIG. 1B, the operation surface 11d and the operation surface 11e meet with the boundary region 12a as a step portion therebetween, as an example. Meanwhile, as shown in FIG. 1C, the operation surface 11b and the operation surface 11e meet in a mountain fold at the boundary region 12d as a boundary line. As described above, the present embodiment is the switch device 1 which includes the operation knob with the operation surfaces of a vertical three-tiered and mountain-fold (outward-fold) type and has nine operating positions as the operation surfaces.

Each of the operation surfaces (11a to 11i) in the above description may be a flat surface or a curved surface.

As shown in FIGS. 1A, 1B and 1C, press detection units (31, 32, 33, 34) are arranged under the operation surfaces (11a, 11c, 11g, 11i). As an example, a tactile switch can be used as the press detection unit (31, 32, 33, 34). By pressing the nine operation surfaces (11a to 11i) of the operation knob 10, the press detection units (31, 32, 33, 34) corresponding to the pressed operation surfaces (11a to 11i) are pressed and turned on. In the present embodiment, based on a combination of on and off of the press detection units (31, 32, 33, 34), the control unit 40 (described later) detects the operation surface (11a to 11i) which has been pressed. Besides the tactile switches, other switches using capacitive pressure sensors or strain gauge load sensors, etc. can be used to detect pressing operations. Pressing (depressing) operations can also be detected by the above-described touch detection electrodes that detect a change in capacitance.

FIG. 2A is a front view showing the switch devices in the embodiment of the invention mounted on a steering wheel of a vehicle when viewed from the driver's seat side, and FIG. 2B is an enlarged front view showing the operation knob of the switch device. The switch device 1 in the embodiment of the invention can be mounted on a steering wheel of a vehicle and serve as a vehicular switch device, as an example. Mounting the switch device 1 on a steering wheel of a vehicle gives an effect that it is possible to easily distinguish between a tracing operation and a pressing operation with fingertip sensation even when not looking at the hand while driving the vehicle.

As shown in FIG. 2A, the switch device 1 is installed on a steering wheel 110 of a vehicle 100 and used as a steering wheel switch. For example, the switch devices 1 are arranged on the left and right of the steering wheel 110 of the vehicle 100. This steering wheel 110 has a horn pad portion 120 to which a steering shaft is connected, a steering wheel gripping portion 111 to be gripped by a user, and spoke portions 112 and 113 that connect the horn pad portion 120 and the steering wheel gripping portion 111.

In the example shown in FIG. 2A, the switch device 1 in the present embodiment is mounted on each of the spoke portions 112 and 113. Then, as shown in FIG. 2B, a function to be executed when tracing or pressing the operation surfaces is indicated by characters or figures, etc. on each operation surface (11a to 11i) of the operation knob 10.

As shown in FIG. 2A, various display units are arranged on an instrument panel 114 and, as an example, it is possible to make changes, etc. on menus, scales, numerical values, etc. displayed on a display unit 115 by operating the switch device 1 mounted on the spoke portion 112. As an example, as shown in FIG. 2B, when the operation surfaces 11a, 11c, 11d, 11f, 11g, and 11i are pressed, the functions of “set,” “return,” “move left,” “move right,” “cancel,” and “switch inter-vehicle distance” are respectively executed. Meanwhile, when tracing the operation surfaces 11b, 11e, and 11h, the scales or numerical values displayed on the display unit 115 can be increased or decreased according to the direction of the tracing operation.

### (Configuration of the Control Unit 40)

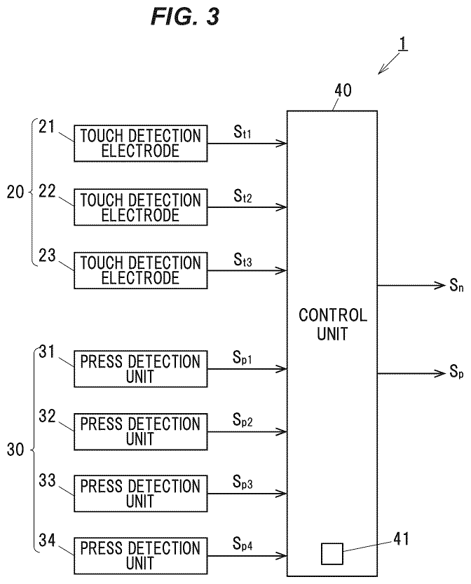

FIG. 3 is a block diagram including the control unit of the switch device in the present embodiment. The control unit 40 is, e.g., a microcomputer composed of a CPU (Central Processing Unit) performing calculation and processing, etc., of the acquired data according to a stored program, and a RAM (Random Access Memory) and a ROM (Read Only Memory) as semiconductor memories, etc. The ROM stores, e.g., a program for operation of the control unit 40. The RAM is used as, e.g., a storage area to temporarily store calculation results, etc.

### (Operation of the Switch Device 1)

As shown in FIG. 3, touch operation signals (Sₜ₁, Sₜ₂, Sₜ₃) are input to the control unit 40 from the touch detection electrodes (21, 22, 23) as the electrostatic capacitance sensors 20. Push signals (Sₚ₁, Sₚ₂, Sₚ₃, Sₚ₄) are also input to the control unit 40 from the press detection units (31, 32, 33, 34) as press position sensors 30. As a result of signal processing operation in the control unit 40, e.g., a tracing signal Sₙ or a position signal Sₚ is output from the control unit 40 to the vehicle 100. On the vehicle 100 side, changes on the menu, scales, numerical values, etc. displayed on the display unit 115 are made based on the tracing signal Sₙ or the position signal Sₚ.

The control unit 40 first generates touch determination signals T₁, T₂, and T₃ in a touch determination signal generation unit 41 based on the input touch operation signals (Sₜ₁, Sₜ₂, Sₜ₃). The touch operation signals (Sₜ₁, Sₜ₂, Sₜ₃) are capacitance values generated between a touching finger of an operator and the touch detection electrodes (21, 22, 23). As shown in Table 1, the touch determination signal generation unit 41 sets T₁=1, T₂=1, and T₃=1 as “with touch” when the capacitance values detected by the touch detection electrodes (21, 22, 23) are not less than a predetermined capacitance threshold value Vₜ, and sets T₁=0, T₂=0, and T₃=0 as “no touch” when less than the predetermined capacitance threshold value Vₜ.

TABLE 1

| | | | Touch |
|---|---|---|---|
| Touch detection | | | determination |
| electrode signal | Determination | | signal |
| Sₜ₁ | Sₜ₁ ≥ Vₜ | With touch on 11b | T₁ = 1 |
| | Sₜ₁ < Vₜ | No touch on 11b | T₁ = 0 |
| Sₜ₂ | Sₜ₂ ≥ Vₜ | With touch on 11e | T₂ = 1 |
| | Sₜ₂ < Vₜ | No touch on 11e | T₂ = 0 |
| Sₜ₃ | Sₜ₃ ≥ Vₜ | With touch on 11h | T₃ = 1 |
| | Sₜ₃ < Vₜ | No touch on 11h | T₃ = 0 |

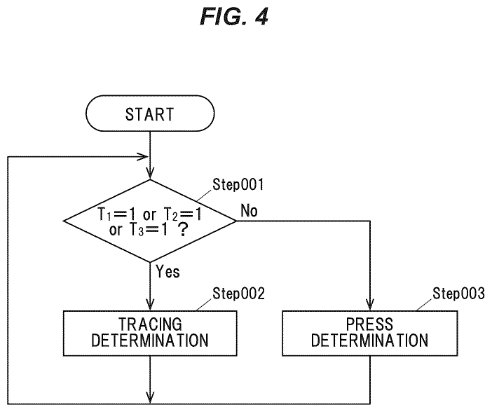

FIG. 4 is a flowchart showing the overall operation of the switch device in the present embodiment. The control unit 40 first determines whether or not a touch operation has been performed, based on the touch determination signals T₁, T₂, and T₃.

(Step 001) The control unit 40 determines whether T₁=1 or T₂=1 or T₃=1. That is, when any of the touch determination signals T₁, T₂, and T₃ is 1 (ON) (Step 001: Yes), it is determined that a touch operation has been performed and the process proceeds to Step 002. When not (Step 001: No), it is determined that a touch operation has not been performed and the process proceeds to Step 003 (press determination).

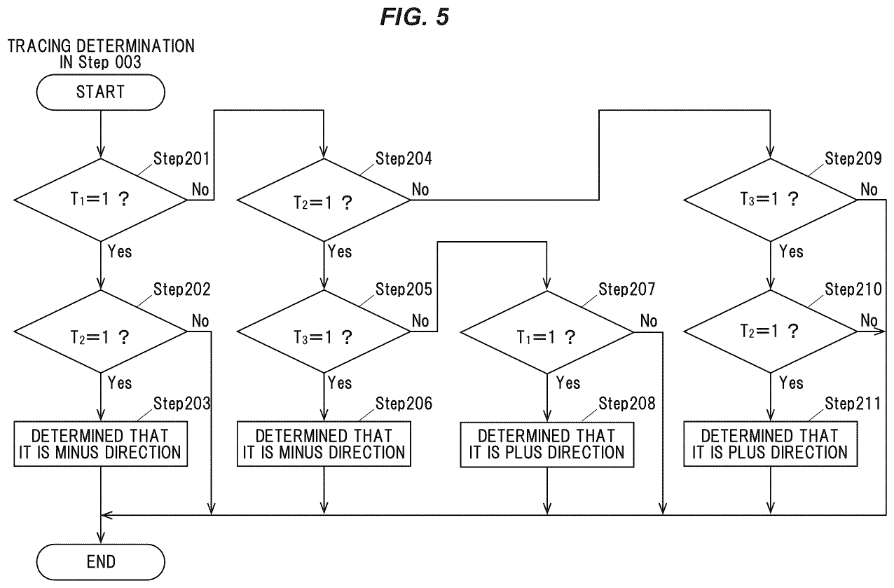

(Step 002) FIG. 5 is a flowchart showing an operation of a tracing determination part in the flowchart shown in FIG. 4. The control unit 40 performs a tracing determination operation in accordance with the flowchart shown in FIG. 5.

(Step 201) The control unit 40 determines whether or not T₁=1. When T₁=1 (Step 201: Yes), the process proceeds to Step 202. When not (Step 201: No), the process proceeds to Step 204.

(Step 202) The control unit 40 determines whether or not T₂=1. When T₂=1 (Step 202: Yes), the process proceeds to Step 203. When not (Step 202: No), the tracing determination operation ends.

(Step 203) The control unit 40 determines that a tracing operation has been performed in the minus direction, and ends the tracing determination operation. The control unit 40 can output a tracing signal Sₙ corresponding to the determination of the tracing in the minus direction.

(Step 204) The control unit 40 determines whether or not T₂=1. When T₂=1 (Step 204: Yes), the process proceeds to Step 205. When not (Step 204: No), the process proceeds to Step 209.

(Step 205) The control unit 40 determines whether or not T₃=1. When T₃=1 (Step 205: Yes), the process proceeds to Step 206. When not (Step 205: No), the process proceeds to Step 207.

(Step 206) The control unit 40 determines that a tracing operation has been performed in the minus direction, and ends the tracing determination operation. The control unit 40 can output a tracing signal Sₙ corresponding to the determination of the tracing in the minus direction.

(Step 207) The control unit 40 determines whether or not T₁=1. When T₁=1 (Step 207: Yes), the process proceeds to Step 208. When not (Step 207: No), the tracing determination operation ends.

(Step 208) The control unit 40 determines that a tracing operation has been performed in the plus direction, and ends the tracing determination operation. The control unit 40 can output a tracing signal Sₙ corresponding to the determination of the tracing in the plus direction.

(Step 209) The control unit 40 determines whether or not T₃=1. When T₃=1 (Step 209: Yes), the process proceeds to Step 210. When not (Step 209: No), the tracing determination operation ends.

(Step 210) The control unit 40 determines whether or not T₂=1. When T₂=1 (Step 210: Yes), the process proceeds to Step 211. When not (Step 210: No), the tracing determination operation ends.

(Step 211) The control unit 40 determines that a tracing operation has been performed in the plus direction, and ends the tracing determination operation. The control unit 40 can output a tracing signal Sₙ corresponding to the determination of the tracing in the plus direction.

On the vehicle 100 side, the scales or numerical values displayed on the display unit 115 are increased or decreased and operations of corresponding in-vehicle devices or electronic devices, etc. are controlled, based on the tracing signal Sₙ output as a result of the tracing determination operation described above.

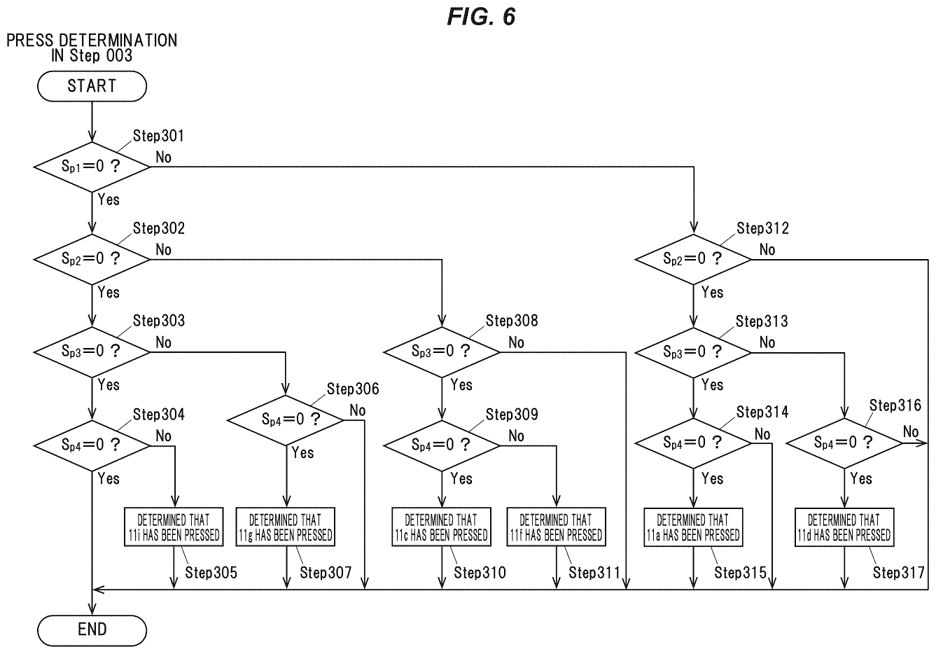

(Step 003) FIG. 6 is a flowchart showing an operation of a press determination part in the flowchart shown in FIG. 4. The control unit 40 performs a press determination operation in accordance with the flowchart shown in FIG. 6. Based on the push signals (Sₚ₁, Sₚ₂, Sₚ₃, Sₚ₄) and a combination of press determinations, the control unit 40 determines which operation surface is the pressed position as shown in Table 2. The push signals (Sₚ₁, Sₚ₂, Sₚ₃, Sₚ₄) output from the press detection units (31, 32, 33, 34) as the press position sensors 30 are set to 1 when pressed (pushed, depressed) and set to 0 when not pressed.

TABLE 2

| | |
|---|---|
| Combinations of press determinations | Determined press |

| Sₚ₁ | Sₚ₂ | Sₚ₃ | Sₚ₄ | position |
|---|---|---|---|---|
| 1 | 0 | 0 | 0 | 11a |
| 0 | 1 | 0 | 0 | 11c |
| 1 | 0 | 1 | 0 | 11d |
| 0 | 1 | 0 | 1 | 11f |
| 0 | 0 | 1 | 0 | 11g |
| 0 | 0 | 0 | 1 | 11i |

(Step 301) The control unit 40 determines whether or not Sₚ₁=0. When Sₚ₁=0 (Step 301: Yes), the process proceeds to Step 302. When not (Step 301: No), the process proceeds to Step 312.

(Step 302) The control unit 40 determines whether or not Sₚ₂=0. When Sₚ₂=0 (Step 302: Yes), the process proceeds to Step 303. When not (Step 302: No), the process proceeds to Step 308.

(Step 303) The control unit 40 determines whether or not Sₚ₃=0. When Sₚ₃=0 (Step 303: Yes), the process proceeds to Step 304. When not (Step 303: No), the process proceeds to Step 306.

(Step 304) The control unit 40 determines whether or not Sₚ₄=0. When Sₚ₄=0 (Step 304: Yes), the press determination operation ends. When not (Step 304: No), the process proceeds to Step 305.

(Step 305) The control unit 40 determines that a pressing operation has been performed on the operation surface 11i, and ends the press determination operation. The control unit 40 can output a position signal Sₚ corresponding to the pressing operation on the operation surface 11i.

(Step 306) The control unit 40 determines whether or not Sₚ₄=0. When Sₚ₄=0 (Step 306: Yes), the process proceeds to Step 307. When not (Step 306: No), the press determination operation ends.

(Step 307) The control unit 40 determines that a pressing operation has been performed on the operation surface 11g, and ends the press determination operation. The control unit 40 can output a position signal Sₚ corresponding to the pressing operation on the operation surface 11g.

(Step 308) The control unit 40 determines whether or not Sₚ₃=0. When Sₚ₃=0 (Step 308: Yes), the process proceeds to Step 309. When not (Step 308: No), the press determination operation ends.

(Step 309) The control unit 40 determines whether or not Sₚ₄=0. When Sₚ₄=0 (Step 309: Yes), the process proceeds to Step 310. When not (Step 309: No), the process proceeds to Step 311.

(Step 310) The control unit 40 determines that a pressing operation has been performed on the operation surface 11c, and ends the press determination operation. The control unit 40 can output a position signal Sp corresponding to the pressing operation on the operation surface 11c.

(Step 311) The control unit 40 determines that a pressing operation has been performed on the operation surface 11f, and ends the press determination operation. The control unit 40 can output a position signal Sₚ corresponding to the pressing operation on the operation surface 11f.

(Step 312) The control unit 40 determines whether or not Sₚ₂=0. When Sₚ₂=0 (Step 312: Yes), the process proceeds to Step 313. When not (Step 312: No), the press determination operation ends.

(Step 313) The control unit 40 determines whether or not Sₚ₃=0. When Sₚ₃=0 (Step 313: Yes), the process proceeds to Step 314. When not (Step 313: No), the process proceeds to Step 316.

(Step 314) The control unit 40 determines whether or not Sₚ₄=0. When Sₚ₄=0 (Step 314: Yes), the process proceeds to Step 315. When not (Step 314: No), the press determination operation ends.

(Step 315) The control unit 40 determines that a pressing operation has been performed on the operation surface 11a, and ends the press determination operation. The control unit 40 can output a position signal Sₚ corresponding to the pressing operation on the operation surface 11a.

(Step 316) The control unit 40 determines whether or not Sₚ₄=0. When Sₚ₄=0 (Step 316: Yes), the process proceeds to Step 317. When not (Step 316: No), the press determination operation ends.

(Step 317) The control unit 40 determines that a pressing operation has been performed on the operation surface 11d, and ends the press determination operation. The control unit 40 can output a position signal Sₚ corresponding to the pressing operation on the operation surface 11d.

On the vehicle 100 side, the scales or numerical values, etc., displayed on the display unit 115 are changed and operations of corresponding in-vehicle devices or electronic devices, etc. are controlled, based on the position signal Sₚ output by the press determination operation described above.

### (Another Embodiment of the Operation Surfaces of the Operation Knob)

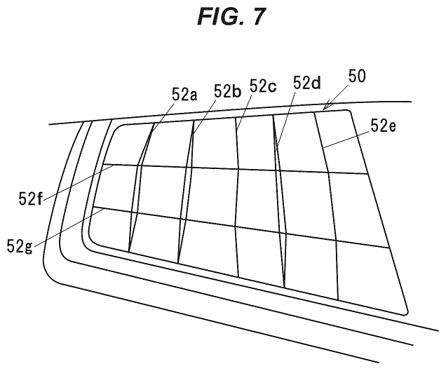

FIG. 7 is a front view showing another embodiment to show another division pattern of the operation knob of the switch device. An operation knob 50 shown in FIG. 7 is of a vertical three-tiered and outward-and-inward fold type.

As shown in FIG. 7, the operation knob 50 has operation surfaces defined by boundary regions (52a, 52b, 52c, 52d, 52e, 52f, and 52g). As an example, the boundary regions (52a, 52b, 52d) are step portions (inclined surfaces) with a level difference, and operation surfaces adjacent with a boundary region therebetween are formed at different angles. Meanwhile, the boundary regions (52c, 52e, 52f, 52g) are boundary lines each formed between two adjacent operation surfaces, and operation surfaces adjacent with a boundary line therebetween are formed at different angles. The adjacent operation surfaces described above can be adjacent one another in a mountain fold (outward fold) or a valley fold (inward fold), and whether the operation surfaces meet in a mountain fold (outward fold) or a valley fold (inward fold) can be set arbitrarily based on the conditions such as details of operations or the position of mounting the operating knob.

### Effects of the Embodiment of the Invention

The configuration described above has the following effects.
(1) By dividing the surface of the control knob into operation surfaces with a grid pattern and varying the angles of the operation surfaces, it is possible to ensure position recognition on an electrostatic capacitance steering wheel switch that has plural positions.
(2) It is possible to realize a seamless electrostatic capacitance steering wheel switch that is easy to recognize plural operating positions, e.g., nine positions, and is designed taking into account tracing operations, slide operations, and pressing operations.
(3) Due to the change in the operation surfaces, a feeling at the time of pressing operation is obtained and it is easy to recognize the position to press. In addition, since reliable feedback of the operation is obtained by climbing over a three-dimensional object, such as the step portion (inclined surface) having a thin relief with a level difference, it is easy to recognize the position to press.
(4) Since feedback is obtained in response to the tracing operation by using a three-dimensional object, such as the step portion (inclined surface) having a thin relief with a level difference, as a guide, it is easy to know the tracing direction of the tracing operation.
(5) It has a seamless, one-surface switch structure, but it can also contribute to adding a multi-faceted cut design.
(6) The switch device 1 can serve as a vehicular switch device mounted on a steering wheel of a vehicle. During driving a vehicle, the switch is sometimes operated while holding the steering wheel without looking at the hand. The effect is that even in such a case, it is easy to distinguish between tracing operation and pressing or depressing operation with fingertip sensation.

Although the embodiment of the invention has been described, this embodiment is merely an example and the invention according to claims is not to be limited thereto. This new embodiment may be implemented in various other forms, and various omissions, substitutions and changes, etc., can be made without departing from the gist of the invention. For example, the invention can be applied to various devices on which the switch device can be mounted, such as a touch pad of personal computer or game controller. In addition, not all combinations of the features described in the embodiment are necessary to solve the problem of the invention. Further, the embodiment is included within the scope and gist of the invention and also within the invention described in the claims and the range of equivalency.

### REFERENCE SIGNS LIST

1 SWITCH DEVICE
10 OPERATION KNOB
11a, 11b, 11c, 11d, 11e, 11f, 11g, 11 h, 11i OPERATION SURFACE
12a, 12b, 12c, 12d BOUNDARY REGION
20 ELECTROSTATIC CAPACITANCE SENSOR
30 PRESS POSITION SENSOR
40 CONTROL UNIT
50 OPERATION KNOB
100 VEHICLE
110 STEERING WHEEL

1. A switch device, comprising:
an operation knob comprising a plurality of operation surfaces; and
an operation detection unit that detects an operation performed by operating one, or not less than two, of the plurality of operation surfaces,
wherein adjacent operation surfaces of the plurality of operation surfaces have different angles with a boundary region therebetween.

2. The switch device according to claim 1, wherein the operation detection unit detects a tracing operation or a pressing operation as the operation on one, or not less than two, of the plurality of operation surfaces.

3. The switch device according to claim 2, further comprising:
a control unit that determines a direction of a tracing operation performed on not less than two of the plurality of operation surfaces and/or determines one of the plurality of operation surfaces that has been pressed, based on a detection result of the operation detection unit.

4. The switch device according to claim 1, wherein the operation detection unit comprises an electrostatic capacitance sensor that is provided in at least a region corresponding to one of the operation surfaces and detects touch or proximity to the operation surface.

5. The switch device according to claim 4, wherein the adjacent operation surfaces meet at the boundary region in a continuous manner, and the electrostatic capacitance sensors are provided in regions respectively corresponding to the adjacent operation surfaces.

6. The switch device according to claim 1, wherein the operation detection unit comprises a tactile switch that is provided under at least one of the plurality of operation surfaces and is turned on and off by a pressing operation.

7. The switch device according to claim 1, wherein the boundary region is a boundary at which the adjacent operation surfaces meet, and comprises a boundary line, or a step portion with a level difference sandwiched between edges of two of the operation surfaces.

8. The switch device according to claim 1, wherein the plurality of operation surfaces comprise the adjacent operation surfaces meeting in a mountain fold or a valley fold at the boundary region, or the adjacent operation surfaces meeting with the step portion therebetween, or a combination thereof.

9. The switch device according to claim 1, wherein each of the plurality of operation surfaces comprises a flat surface or a curved surface.

10. A vehicular switch device, comprising:
the switch device according to claim 1 that is mounted on a steering wheel of a vehicle.
